(19) United States
(12) Patent Application Publication
(10) Pub. No.: US 2009/0026443 A1
(43) Pub. Date: Jan. 29, 2009

(54) ORGANIC THIN-FILM TRANSISTOR AND METHOD OF MANUFACTURE THEREOF

(75) Inventor: Satoru Ohta, Saitama (JP)

Correspondence Address: SUGHRUE MION, PLLC, 2100 PENNSYLVANIA AVENUE, N.W., SUITE 800, WASHINGTON, DC, 20037, US

(73) Assignee: PIONEER CORPORATION, Meguro-ku, Tokyo (JP)

(21) Appl. No.: 11/908,645

(22) PCT Filed: Mar. 13, 2006
(86) PCT No.: PCT/JP2006/305314

§ 371 Date: Nov. 14, 2007

(30) Foreign Application Priority Data
Mar. 15, 2005 (JP) 2005-073283

(51) Int. Cl. H01L 51/05; H01L 51/40

(52) U.S. Cl. 257/40; 438/99; 257/E51.005

(57) ABSTRACT

A durable organic thin-film transistor and a method of manufacture thereof, the organic thin-film transistor having: a source electrode and a drain electrode arranged mutually separated; an organic semiconductor layer interposed between the source electrode and the drain electrode; and a gate electrode arranged to face said organic semiconductor layer which is between said source electrode and said drain electrode, with a gate insulating film being provided between said gate electrode and said organic semiconductor layer, wherein the gate insulating film includes an organic compound and particles of an inorganic compound dispersed in the organic compound, and a flattened film is provided between the source electrode and the drain electrode, or the gate electrode and the gate insulating film.

### TECHNICAL FIELD

The present invention relates to an organic thin-film transistor and a method of manufacture thereof.

### BACKGROUND ART

In recent years, light-emitting elements such as for example organic EL elements employing organic compound materials, that utilize electroluminescence (hereinbelow abbreviated as EL), in which light is emitted in an electrical field due to generation of charges in a substance, movement of charges, photoconduction or recombination of charges have attracted attention. Organic EL display devices, in which a plurality of self-luminescent organic EL elements are mounted in matrix fashion are attracting attention as next-generation displays, on account of their superiority to conventional liquid crystals, in that for example they provide higher contrast, wider field of view, faster response, and can be driven with lower voltage than liquid crystals.

Also, concurrently with research into organic EL elements, recently, considerable research is being conducted into organic thin-film transistors (organic TFTs). It is expected that these might be applied for example to flexible displays. The performance of an organic TFT itself is about the same as that of an amorphous silicon TFT; however, to the extent that it is being used as a liquid crystal or electrophoretic drive element, as regards the performance of an organic TFT, there is no problem if there is a certain degree of on/off ratio.

Also, in an attempt to maximize the benefits to be obtained from organic TFTs, attempts are being made to form organic TFTs by a printing technique and gate insulating film materials are being studied that are dissolved in a polymer solvent in order to achieve this. Gate insulating films are being studied in which nanoparticles of metallic oxide of high dielectric constant are simply dispersed in a polymer, in order to form such a polymer gate insulating film of high dielectric constant. (See Laid-open Japanese Patent Application No. 2002-110999)

### DISCLOSURE OF THE INVENTION

When organic TFTs are applied to a flexible substrate, there is concern that the bending strength of the inorganic gate insulating film may become a problem.

Also, in order to drive an organic EL element, which is a self-luminescent element, a large current is necessary in order to produce light emission. In studies aimed at securing a high dielectric constant of the gate insulating film, not many types of polymer of high dielectric constant are available and their voltage withstanding ability is low, so, as a result, the polymer film must be made of large thickness: thus a situation arises in which the requirements of high dielectric constant and voltage withstanding ability are contradictory. Furthermore, polymers of high dielectric constant are difficult to dissolve in solvents, making formation by printing difficult.

Also, in the case where metallic oxides of high dielectric constant are dispersed in the polymer, the surface of the gate insulating film becomes rough due to the nanoparticles projecting at the surface, causing a lowering of the performance of the organic thin-film transistor.

The present invention therefore provides, as an example, a durable organic thin-film transistor wherein such deterioration in performance is absent and a method of manufacture thereof.

An organic thin-film transistor according to claim 1 comprises: a source electrode and a drain electrode arranged mutually separated; an organic semiconductor layer interposed between the source electrode and the drain electrode; and a gate electrode arranged to face the organic semiconductor layer which is between the source electrode and the drain electrode, with a gate insulating film being provided between the gate electrode and the organic semiconductor layer, characterized in that the gate insulating film comprises an organic compound and particles of an inorganic compound dispersed in the organic compound, and a flattened film is provided between the source electrode and the drain electrode, or the gate electrode and the gate insulating film.

A method of manufacturing an organic thin-film transistor according to claim 5 is for an organic thin-film transistor having: a source electrode and a drain electrode arranged mutually separated; an organic semiconductor layer interposed between the source electrode and the drain electrode; and a gate electrode arranged to face the organic semiconductor layer which is between the source electrode and the drain electrode, with a gate insulating film being provided between the gate electrode and the organic semiconductor layer, the method comprising: a step of forming the gate insulating film comprising an organic compound and particles of an inorganic compound dispersed in the organic compound; and a step of forming a flattened film on the gate insulating film after the step of forming the gate insulating film.

### BRIEF DESCRIPTION OF THE DRAWINGS

FIG. 1 is a partial cross-sectional view of an organic TFT according to an embodiment of the present invention;

FIG. 2 is a partial cross-sectional view of an organic TFT according to an embodiment of the present invention; and

FIG. 3 is a partial cross-sectional view of an organic TFT according to another embodiment of the present invention.

### MODE FOR CARRYING OUT THE INVENTION

An organic thin-film transistor according to an embodiment of the present invention and a method of manufacture thereof are described below with reference to the drawings.

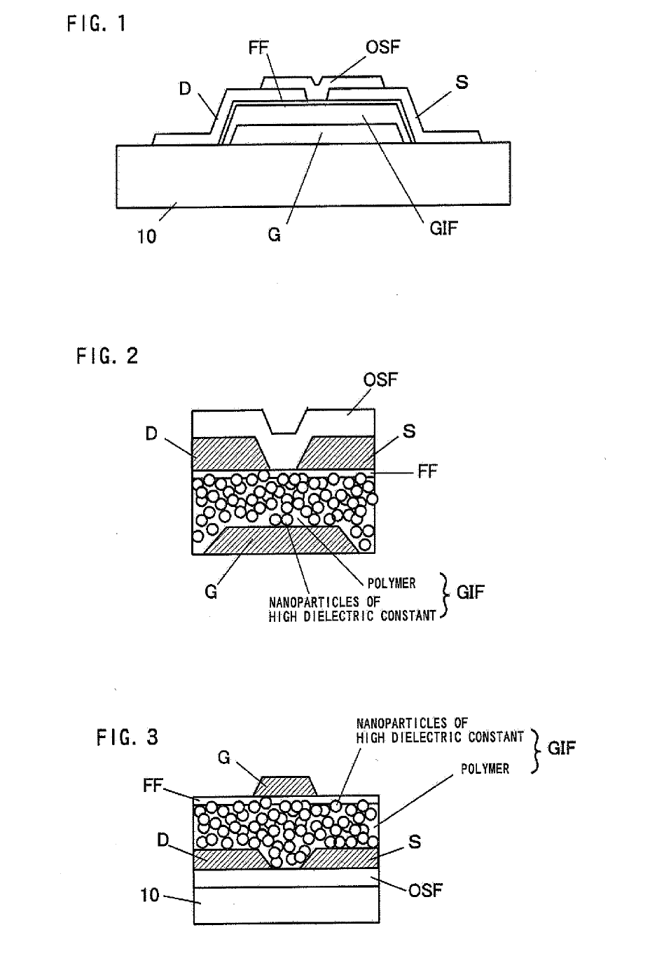

FIG. 1 shows a cross-sectional view of an organic thin-film transistor.

FIG. 1 shows an example of the construction of a bottom contact type organic TFT 11. An organic TFT includes: a facing source electrode S and drain electrode D, an organic semiconductor film OSF comprising an organic semiconductor laminated so as to make it possible to form a channel between the source electrode and drain electrode, and a gate electrode G for applying an electrical field to the organic semiconductor film OSF between the source electrode S and drain electrode D; and a gate insulating film GIF that covers the gate electrode G and insulates this from the source electrode S and drain electrode D is provided. In addition, the organic TFT 11 is provided with a flattened film FF between the source electrode S and drain electrode D and gate electrode GIF.

With this embodiment, lowering of performance of the organic TFT caused by increase in roughness of the surface of the gate insulating film GIF due to nanoparticles can be prevented by a flattening film FF formed on the gate insulating film GIF in which nanoparticles of dielectric material of high dielectric constant are dispersed in the polymer as shown in FIG. 2.

(Substrate)

Apart from glass, the substrate 10 may be a plastic substrate made of for example PES, PS or PC, or a substrate made by sticking together glass and plastic, or a substrate whose surface is coated with an alkali barrier film or gas barrier film. As the plastic substrate, films made of for example polyethylene terephthalate, polyethylene-2,6-naphthalate, polysulfone, polyethersulfone, polyether-ether ketone, polyphenoxyether, polyallylate, fluorine resin, or polypropylene may be employed.

(Organic TFT)

As an organic semiconductor of an organic semiconductor film OSF, pentacene may be employed. However, there is no restriction to this, and any organic material having semiconductor properties may be employed. Examples that may be cited include, as low molecular weight materials: phthalocyanin-based derivatives, naphthalocyanin-based derivatives, azo compound-based derivatives, perylene-based derivatives, indigo-based derivatives, quinacrylidone-based derivatives, or heterocyclic quinone-based derivatives such as anthraquinones, cyanin-based derivatives, Fullerene derivatives, or nitrogen-containing cyclic compounds such as indole, carbazole, oxazole, inoxazole, thiazole, imidazole, pyrazole, oxadiazole, pyrazolin, thiathiazole, or triazole, hydrazine derivatives, triphenylamine derivatives, triphenylmethane derivatives, stilbenes, quinone compound derivatives such as anthraquinone, diphenoquinone, or polycyclic aromatic compound derivatives such as anthracene, pyrene, phenanthrene, or coronene. Polymeric materials that may be used include: aromatic conjugate polymers such as polyparaphenylene, aliphatic conjugate polymers such as polyacetylene, heterocyclic conjugate polymers such as polypinole or polythiophenes, conjugate copolymers containing a hetero atom such as polyanilines or polyphenylene sulfide or carbon-based conjugate polymers such as heterocyclic polymers having a construction in which conjugate polymer structural units are alternately coupled, such as poly(phenylene vinylene), poly(anilene vinylene) or poly(thienylene vinylene). Also, polysilanes or oligosilanes such as disilanylene carbon-based conjugate polymer structures such as disilanylene allylene polymers, (disilanylene) ethenylene polymers, or (disilanylene) ethynylene polymers, or polymers having alternately linked carbon-based conjugate structures may be employed. Apart from these, polymer chains comprising for example phosphorus type or nitrogen type or the like inorganic elements may be employed; in addition, polymers in which there are arranged aromatic type ligands of polymer chains, such as phthalocyanate polysiloxane, fused ring polymers obtained by heat treatment of perylenes such as perylene tetracarboxylic acid, ladder type polymers obtained by heat treatment of polyethylene derivatives having a cyano group, such as polyacrylonitrile, and, in addition, composite materials wherein an organic compound is intercalated in a perovskite may be employed.

Chromium (Cr) alone or Cr/Au may be employed for the gate electrode G or source/drain electrodes S. D, though there is no particular restriction as to material and any material having sufficient conductivity may be employed. Specifically, Pt, Au, W, Ru, Ir, Al, Sc, Ti, V, Mn, Fe, Co, Ni, Zn, Ga, Y, Zr, Nb, Mo, Tc, Rh, Pd, Ag, Cd, Ln, Sn, Ta, Re, Os, Tl, Pb, La, Ce, Pr, Nd, Pm, Sm, Eu, Gd, Tb, Dy, Ho, Er, Tm, Yb, or Lu etc. may be used in the form of the metal on its own or laminated in layers or in the form of chemical compounds. Also, metallic oxides such as ITO or IZO, or organic conductive materials including conjugate polymer compounds are such as polyanilines, polythiophenes or polypyrroles may be employed.

The nanoparticles of high dielectric constant having a high dielectric constant dispersed in the gate insulating film GIF are obtained using Ta₂O₅, but there is no restriction to this. However, a dielectric constant of the nanoparticles of at least 10 is desirable. Specific examples of such nanoparticle materials include TiO₂, ZrO₂, BaTiO₃, PbTiO₃, CaTiO₃, MgMiO₃, BaZrO₃, PbZrO₃, SrZrO₃, CaZrO₃, LaTiO₃, LaZrO₃, BiTiO₃, LaPbTiO₃ and Y₂O₃. Two or more types of these nanoparticle materials may be mixed. Also, preferably the nanoparticle diameter is equal to or less than 500 nm and more preferably is equal to or less than 100 nm.

As the organic compound of the carrier polymer in which the nanoparticles of high dielectric constant of the gate electrode film GIF are dispersed, a mixture of polyvinylphenol and methylated melamine formaldehyde copolymer may be employed, but there is no restriction to this, so long as the material has insulating properties. As other examples of the polymer of the gate insulating film GIF, there may be employed for example polyethylene, polyvinyl chloride, polyvinylidene fluoride, polycarbonate, polyphenylene sulfide, polyether ether ketone, polyether sulfone, polyimide, phenol novolak, polyamide, benzocyclobutene, polychloropyrene, polyester, polyoxymethylene, polysulfone, epoxy resin, or polyvinyl alcohol, or resins such as polyacrylates. Apart from these resins that are hardened by heat or light are effective.

As the flattened film FF, the inorganic compound Si₃N₄ is employed. However, apart from this, as inorganic compounds, metal oxides such as LiOₓ, LiNₓ, NaOₓ, KOₓ, RbOₓ, CsOₓ, BeOₓ, MgOₓ, MgNₓ, CaOₓ, CaNₓ, SrOₓ, BaOₓ, ScOₓ, YOₓ, YNₓ, LaOₓ, LaNₓ, CeOₓ, PrOₓ, NdOₓ, SmOₓ, EuOₓ, GdOₓ, TbOₓ, DyOₓ, HoOₓ, ErOₓ, TmOₓ, YbOₓ, LuOₓ, TiOₓ, TiOₓ, ZrOₓ, ZrNₓ, HfOₓ, HfNₓ, ThOₓ, VOₓ, VNₓ, NbOₓ, TaOₓ, TaNₓ, CrOₓ, CrNₓ, MoOₓ, MoNₓ, WOₓ, WNₓ, MnOₓ, ReOₓ, FeOₓ, FeNₓ, RuOₓ, OsOₓ, CoOₓ, RhOₓ, IrOₓ, NiOₓ, PdOₓ, PtOₓ, CuOₓ, CuNₓ, AgOₓ, AuOₓ, ZnOₓ, CdOₓ, HgOₓ, BOₓ, BNₓ, AlOₓ, AlNₓ, GaOₓ, GaNₓ, InOₓ, TiOₓ, TiNₓ, SiNₓ, GeOₓ, SnOₓ, PbOₓ, POₓ, PNₓ, AsOₓ, SbOₓ, SeOₓ, or TeOₓ, noble metal composite oxides such as LiAlO₂, Li₂SiO₃, Li₂TiO₃, Na₂Al₂₂O₃₄, NaFeO₂, Na₄SiO₄, K₂SiO₃, K₂TiO₃, K₂WO₄, Rb₂CrO₄, Cs₂CrO₄, MgAl₂O₄, MgFe₂O₄, MgTiO₃, CaTiO₃, CaWO₄, CaZrO₃, SrFe₁₂O₁₉, SrTiO₃, SrZrO₃, BaAl₂O₄, BaFe₁₂O₁₉, BaTiO₃, Y₃A₁₅O₁₂, Y₃Fe₅O₁₂, LaFeO₃, La₃Fe₅O₁₂, La₂Ti₂O₇, CeSnO₄, CeTiO₄, Sm₃Fe₅O₁₂, EuFeO₃, Eu₃Fe₅O₁₂, GdFeO₃, Gd₃Fe₅O₁₂, DyFeO₃, DyFe₅O₁₂, HoFeO₃, Ho₃Fe₅O₁₂, ErFeO₃, Er₃Fe₅O₁₂, Tm₃Fe₅O₁₂, LuFeO₃, Lu₃Fe₅O₁₂, NiTiO₃, Al₂TiO₃, FeTiO₃, BaZrO₃, LiZrO₃, MgZrO₃, HfTiO₄, NH₄VO₃, AgVO₃, LiVO₃, BaNb₂O₆, NaNbO₃, SrNb₂O₆, KTaO₃, NaTaO₃, SrTa₂O₆, CuCr₂O₄, Ag₂CrO₄, BaCrO₄, K₂MoO₄, Na₂MoO₄, NiMoO₄, BaWO₄, Na₂WO₄, SrWO₄, MnCr₂O₄, MnFe₂O₄, MnTiO₃, MnWO₄, CoFe₂O₄, ZnFe₂O₄, FeWO₄, CoMoO₄, CuTiO₃, CuWO₄, Ag₂MoO₄, Ag₂WO₄, ZnAl₂O₄, ZnMoO₄, ZnWO₄, CdSnO₃, CdTiO₃, CdMoO₄, CdWO₄, NaAlO₂, MgAl₂O₄, SrAl₂O₄, Gd₃Ga₅O₁₂, InFeO₃, MgIn₂O₄, Al₂TiO₅, FeTiO₃, MgTiO₃, Na₂SiO₃, CaSiO₃, ZrSiO₄, K₂GeO₃, Li₂GeO₃, Na₂GeO₃, BiSn₃O₉, MgSnO₃, SrSnO₃, PbSiO₃, PbMoO₄, PbTiO₃, SnO₂—Sb₂O₃, CuSeO₄, Na₂SeO₃, ZnSeO₃, K₂TeO₃, K₂TeO₄, Na₂TeO₃, or Na₂TeO₄, sulfides such as FeS, Al₂S₃, MgS or ZnS, fluorides such as LiF, MgF₂, or SmF₃, chlorides such as HgCl, FeCl₂, or CrCl₃, bromides such as AgBr, CuBr, or MnBr₂, iodides such as PbI₂, CuI, or FeI₂, or metal oxide nitrides such as SiAlON are effective. In the above material designations, the subscript x e.g., in Nₓ, Oₓ etc. indicates an atomic ratio.

Also, when an organic compound is employed as the flattened film FF, any polymer having insulating properties can be employed. Examples that may be employed are: PMMA, polyethylene, polyvinyl chloride, polyvinylidene fluoride, polycarbonate, polyphenylene sulfide, polyether ether ketone, polyether sulfone, polyimide, phenol novolak, polyimide, benzocyclobutene, polychloropyrene, polyester, polyoxymethylene, polysulfone, or resins such as epoxy resin, polyvinyl alcohol, or polyacrylate. Apart from these, resins that are hardened by heat or light are effective.

If the polymer of the gate insulating film GIF has reactive functional groups, a monomolecular film produced using a silane coupling agent may be effective as a flattened film, in particular if the particle diameter of the nanoparticles is small.

However, in the use of such a flattened film, attention must be paid to the film thickness. If the film thickness is too great, the benefit in terms of high dielectric constant of the nanoparticles is small and, as a result, a high dielectric constant of the gate insulating film cannot be achieved. Preferably, the film thickness of the flattened film is equal to or less than 50 nm and even more preferably is equal to or less than 10 nm. In addition, for the flattened film, multiple layers may be used instead of a single layer and each layer may be made of different material.

Film sealing using for example a nitride inorganic-based material such as silicon nitride or polymer-based material is performed so as to cover the back face of the organic TFT and the circuit that is formed. Sealing using an inorganic sealing film comprising a nitride-oxide such as silicon nitride-oxide, an oxide such as silicon oxide or aluminium oxide or a carbide such as silicon carbide, or, apart from this, multi-layer sealing using polymer and inorganic film may be employed.

As shown in FIG. 3, apart from a bottom contact type organic TFT as shown in FIG. 1, as another embodiment, a top contact type organic TFT may be constructed. In the case of a top contact type element, the order of lamination is the opposite of a bottom contact type element, in that an organic semiconductor film OSF is first formed on a substrate 10 and the source electrode S and drain electrode D are formed thereon; and the gate electrode film GIF, flattened film FF and gate electrode G are formed next. The efficiency of electric field application is thereby improved, since the interface of the gate electrode G and gate electrode film GIF can be flattened.

### PRACTICAL EXAMPLES

Organic EL panels comprising actively driven organic TFTs were manufactured and their performance evaluated.

### Practical Example 1

Chromium (Cr) was deposited as a gate electrode on a glass substrate, and subjected to patterning using etching. On top of the gate electrode, a solution consisting of a mixture of 7 wt % of Ta₂O₅ (average particle diameter 50 nm), which is a compound of high dielectric constant, 8 wt % of polyvinyl phenol (Mw=20,000) and 4 wt % of methylated polymelamine-formaldehyde copolymer (Mn=511) were applied by spin coating at 20,000 rpm, dried for two minutes at 100° C., and a gate insulating film formed by hardening for five minutes at 200° C. On the gate insulating film, Si₃N₄ was deposited in a thickness of 5 nm by a sputtering method as a flattening film. After this, a source electrode and drain electrode made of Au were patterned by the lift-off technique using a 5 nm Cr film as an adhesive layer. Finally, an organic TFT was manufactured by depositing a film of pentacene by vacuum evaporation, as an organic semiconductor layer.

### Practical Example 2

Chromium (Cr) was deposited as a gate electrode on a glass substrate and patterning performed by etching. On top of the gate electrode, a solution consisting of a mixture of 7 wt % of Ta₂O₅ (average particle diameter 50 nm), which is a compound of high dielectric constant, 8 wt % of polyvinyl phenol (Mw=20,000) and 7 wt % of methylated polymelamine-formaldehyde copolymer (Mn=511) were applied by spin coating at 2,000 rpm, dried for two minutes at 100° C., and a gate insulating film formed by hardening for five minutes at 200° C. On the gate insulating film, polymethyl methacrylate was deposited in a thickness of 10 nm by a spin coating method as a flattening film. After this, an organic TFT was manufactured by depositing pentacene by vacuum evaporation as an organic semiconductor layer, followed, finally, by patterning by a metal mask by vacuum evaporation a source electrode and drain electrode made of Au.

### Practical Example 3

Chromium (Cr) was deposited as a gate electrode on a glass substrate and patterning performed by etching. On top of the gate electrode, a solution consisting of a mixture of 7 wt % of Ta₂O₅ (average particle diameter 50 nm), which is a compound of high dielectric constant, 8 wt % of polyvinyl phenol (Mw=20,000) and 4 wt % of methylated polymelamine-formaldehyde copolymer (Mn=511) were applied by spin coating at 2,000 rpm, dried for two minutes at 100° C., and a gate insulating film formed by hardening for five minutes at 200° C. A self-organizing monomolecular film of octadecyl trichlorosilane of a number of nm was then formed as a flattened film on the gate insulating film by a self-organizing method such as for example exposure to octadecyl trichlorosilane vapor. After this, a source electrode and drain electrode made of Au were patterned by the lift-off technique using a 5 nm Cr film as an adhesive layer. Finally, an organic TFT was manufactured by depositing a film of pentacene by vacuum evaporation, as an organic semiconductor layer.

For comparison, an organic TFT of identical construction was manufactured, with the exception that this comparison organic TFT was not provided with a flattened film.

Compared with the organic TFT in which no flattened film was provided, the organic TFTs of the above practical examples, in which flattened films were formed on a gate insulating film made of polymer in which nanoparticles of high dielectric constant were dispersed showed little variation of dielectric constant and their surface roughness (rms (nm)) was reduced to about ⅕ to 1/17; furthermore, mobility (cm²/V_{S}) was increased by an order of magnitude. Also, the threshold voltage Vth (V) was shifted to the low-voltage side.

The present application is based on Japanese Patent Application No. 2005-073283 and incorporates the disclosure of this application by reference.

1-8. (canceled)

9. An organic thin-film transistor comprising: a source electrode and a drain electrode arranged mutually separated; an organic semiconductor layer interposed between said source electrode and said drain electrode; and a gate electrode arranged to face said organic semiconductor layer which is between said source electrode and said drain electrode, with a gate insulating film being provided between said gate electrode and said organic semiconductor layer, wherein said gate insulating film comprises an organic compound and particles of an inorganic compound dispersed in said organic compound, and wherein a flattened film is provided between said source electrode and said drain electrode, or said gate electrode and said gate insulating film, and wherein the film thickness of the flattened film is equal to or less than 50 nm.

10. The organic thin-film transistor according to claim 9, wherein the particles of said inorganic compound have a dielectric constant of at least 10.

11. The organic thin-film transistor according to claim 9, wherein each of said particles of the inorganic compound has a diameter equal to or less than 500 nm.

12. The organic thin-film transistor according to claim 9, wherein said gate electrode is formed on a resin substrate.

13. The organic thin-film transistor according to claim 9, wherein said flattened film comprises an organic compound or an inorganic compound.

14. A method of manufacturing an organic thin-film transistor having: a source electrode and a drain electrode arranged mutually separated; an organic semiconductor layer interposed between said source electrode and said drain electrode; and a gate electrode arranged to face said organic semiconductor layer which is between said source electrode and said drain electrode, with a gate insulating film being provided between said gate electrode and said organic semiconductor layer,
said method comprising:
a step of forming said gate insulating film comprising an organic compound and particles of an inorganic compound dispersed in said organic compound; and
a step of forming a flattened film on said gate insulating film after said step of forming said gate insulating film, and wherein the film thickness of the flattened film is equal to or less than 50 nm.

15. The method of manufacturing an organic thin-film transistor according to claim 14, wherein said step of forming a flattened film includes a step of forming said flattened film by a sputtering method.

16. The method of manufacturing an organic thin-film transistor according to claim 14, wherein said step of forming a flattened film includes a step of forming said flattened film by a spin-coating method.

17. The method of manufacturing an organic thin-film transistor according to claim 14, wherein said step of forming a flattened film includes a step of forming said flattened film by a self-organizing method.

18. The method of manufacturing an organic thin-film transistor according to claim 9, wherein each of said particles of the inorganic compound has a diameter equal to or less than 500 nm.
